(19) United States
(12) Patent Application Publication
(10) Pub. No.: US 2020/0211670 A1
(43) Pub. Date: Jul. 2, 2020

(54) BIT SCAN METHOD FOR PARTIAL PAGE PROGRAM AND NONVOLATILE MEMORY

(71) Applicant: GigaDevice Semiconductor (Beijing) Inc., Beijing (CN)

(72) Inventor: Minyi CHEN, Beijing (CN)

(21) Appl. No.: 16/279,072

(22) Filed: Feb. 19, 2019

(30) Foreign Application Priority Data
Dec. 30, 2018 (CN) 201811644301.2

(51) Int. Cl. G11C 29/42; G11C 16/04; G11C 16/10; G11C 16/34; G11C 16/24; G06F 11/10; G11C 29/52

(52) U.S. Cl. CPC G11C 29/42; G11C 16/0483; G11C 16/10; G11C 29/52; G11C 16/24; G06F 11/1068; G11C 16/3459

(57) ABSTRACT

Disclosed are a bit scan method for a partial page program, a partial page program method and a nonvolatile memory. The partial page program is performed on a m-bit selected portion of a n-bit data region of a page according to m-bit target binary data. The bit scan method includes: counting, only in the selected portion, memory cells which are not correctly programmed. The nonvolatile memory includes a controller and a page having a n-bit data region. The controller is configured to: perform a partial page program on a m-bit portion of the data region according to m-bit target binary data, perform program verification to obtain verification result of the partial page program, and count failed bits in the m-bit portion.

### CROSS-REFERENCE TO RELATED APPLICATIONS

This application claims priority to a Chinese patent application No. 201811644301.2, filed on Dec. 30, 2018, the disclosure of which is incorporated herein by reference in its entirety.

### TECHNICAL FIELD

Embodiments of the present disclosure relate generally to semiconductor memory devices. More particularly, embodiments of the present disclosure relate to a bit scan method for a partial page program and a nonvolatile memory.

### BACKGROUND

Nonvolatile memory device is widely used for data storage applications, and becomes an indispensable component of modern electronic systems, such as personal computers, cellular phones, digital cameras, automotive systems, global positioning systems and the like. Data stored in the nonvolatile memory is not lost when the power supply is removed.

Flash memory is a representative nonvolatile memory device, and is divided into NOR flash memory and NAND flash memory in accordance with a configuration of memory cells. In the NOR flash memory, each of the memory cells is connected independently to a bit line and a word line, and so the NOR flash memory has excellent random access time. Whereas, in the NAND flash memory, only one contact is required for one memory cell string because memory cells are connected in series, and so the NAND flash memory has excellent characteristics for integration. Accordingly, the NAND flash memory has been generally employed in high density flash memory.

Operations of the flash memory typically include program (write), erase and read. Data is programmed into a flash memory by changing threshold voltages of memory cells of the flash memory. Data is read from the flash memory by identifying correspondences between threshold voltages and the threshold voltage distributions representing different data states. The capacity of NAND flash memory has increased remarkably in the past decades. Typically, the NAND flash memory is programmed in page. For a current NAND flash memory, the size of the page may be larger than 16K bytes (1 byte=8 bits), the program operation consumes a lot of time and power.

### SUMMARY

The following is a summary of a subject matter described herein in detail.

According to a first aspect of the present disclosure, a bit scan method for a partial page program is provided. The partial page program is performed on a m-bit selected portion of a n-bit date region of a page of a NAND flash memory according to m-bit target data, where m is less than n. The method includes counting failed bits only in the selected portion. The failed bits refers to memory cells in the selected portion which are not correctly programmed.

According to a second aspect of the present disclosure, provided is a partial page program method applied to a NAND flash memory including a page having a n-bit data region and an ECC region. The partial page program method includes performing a partial page program on a m-bit portion of the data region according to m-bit target binary data, where m is less than n; and counting failed bits in the m-bit portion.

According to a third aspect of the present disclosure, a NAND flash memory is provided. The NAND flash memory includes a page having a n-bit data region and an ECC region; a first buffer; a second buffer; and a controller. The controller is configured to: load m-bit target binary data into the second buffer; perform a partial page program on a m-bit portion of the data region according to the m-bit target binary data, where m is less than n; perform a program verification for the partial page program and retain verification data in the second buffer; and count failed bits in the m-bit portion.

According to the present disclosure, the bit scan operation for the partial page program operation is only performed on a portion of the page where the partial page program is performed. The time and power costs are reduced compared with a full page bit scan.

### BRIEF DESCRIPTION OF DRAWINGS

The accompanying drawings are used for providing further understanding of the present disclosure and constitute a part of this specification. Elements and/or components in the figures are not necessarily drawn to scale.

FIG. 1 is a simplified block diagram of a flash memory according to an embodiment of the present disclosure.

FIG. 2 is a schematic diagram of an exemplary configuration of a memory cell block according to an embodiment of the present disclosure.

FIG. 3 is a schematic diagram of an exemplary configuration of a memory cell page according to an embodiment of the present disclosure.

FIG. 4 is a schematic diagram illustrating an example of a bit scan operation according to an embodiment of the present disclosure.

FIG. 5 is a schematic diagram illustrating another example of the bit scan operation according to an embodiment of the present disclosure.

FIG. 6 is a schematic diagram of a selected portion in a page for a partial page program.

FIG. 7 is a schematic diagram illustrating a bias arrangement of the page in the partial page program.

FIG. 8 is a schematic diagram of another selected portion in a page for a partial page program.

FIG. 9 is a flowchart of a partial page program method according to an embodiment of the present disclosure.

FIG. 10 is a simplified block diagram of another flash memory according to an embodiment of the present disclosure.

FIG. 11 is a flowchart of a partial page program method for the flash memory in FIG. 10.

### DETAILED DESCRIPTION

Example embodiments of the present disclosure will be more clearly understood from the detailed description taken in conjunction with the accompanying drawings. Various example embodiments of the present disclosure will now be described more fully with reference to the accompanying drawings in which some example embodiments of the disclosure are shown. In the drawings, the sizes or configurations of elements may be idealized or exaggerated for clarity.

Detailed illustrative embodiments of the present disclosure are disclosed herein. However, specific structural and functional details disclosed herein are merely representative for purposes of describing example embodiments of the present disclosure. This disclosure, however, may be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present disclosure. As used herein, the term “and/or” includes any and all combinations of one or more of the associated listed items.

It will be understood that when an element is referred to as being “connected” to another element, it can be directly connected to the other element or intervening elements may be present. In contrast, when an element is referred to as being “directly connected” to another element, there are no intervening elements present.

The terminology used herein is for the purpose of describing particular embodiments only and is not intended to be limiting of example embodiments of the disclosure. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

Various embodiments of the present disclosure provide a NAND flash memory. The NAND flash memory is a single-level cell (SLC) NAND flash memory, which just stores one binary bit per memory cell. Each memory cell of the SLC NAND flash memory has two states. One state is referred to as an erased state, and the other state is referred to as a programmed state. The SLC flash memory uses a single reference voltage to read (identify) the binary bit stored in the memory cell.

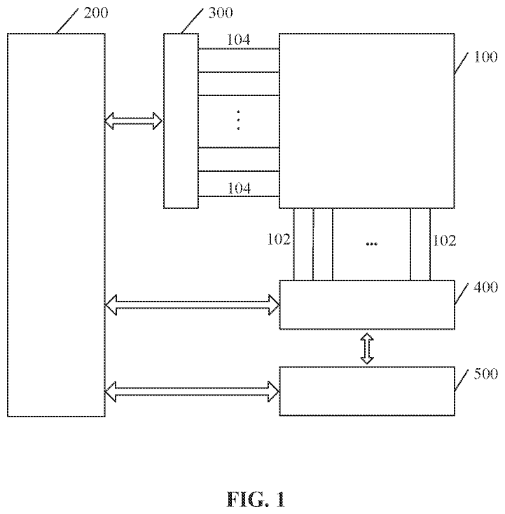

By referring to FIG. 1 to FIG. 3, a description of a structure example of the NAND flash memory is given below. FIG. 1 is a simplified block diagram of a NAND flash memory according to an embodiment of the present disclosure. As shown in FIG. 1, the NAND flash memory 10 includes: a memory cell array 100, a controller 200, a row decoder 300, a page buffer 400, and a bit scan circuit 500.

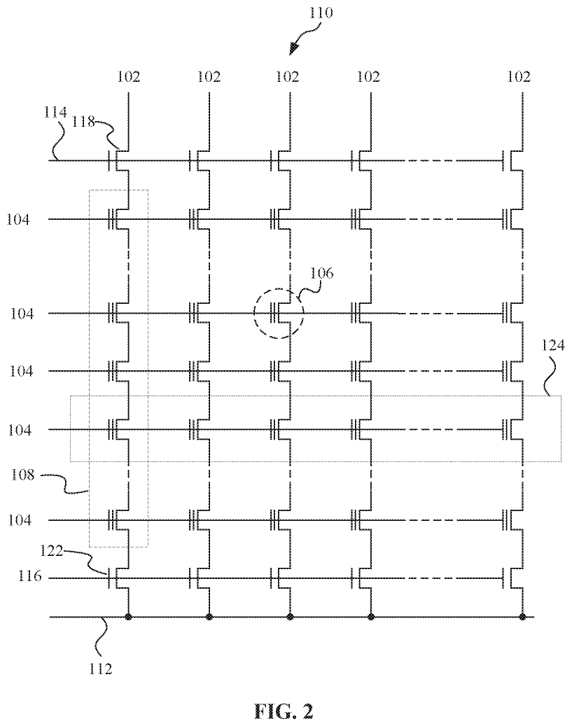

The memory cell array 100 of the NAND flash memory 10 includes multiple memory cell blocks. FIG. 2 shows an exemplary configuration of a memory cell block. As shown in FIG. 2, the memory cells 106 are arranged in rows and columns, and are addressed through word lines 104 and bit lines 102. Each block includes multiple pages. Each page includes a row of memory cells 106. Each memory cell 106 corresponds to one bit.

The controller 200 is connected to the row decoder 300, the page buffer 400, and the bit scan circuit 500. The controller 200 is further connected to a host (not shown). The controller 200 is configured to accept target data to be wrote into the memory cell array 100 from the host, and also configured to output data retrieved from the memory cell array 100 to the host.

The row decoder 300 is connected to the word lines 104. The page buffer 400 is connected to the bit lines 102. The row decoder 300 may be utilized in conjunction with a program voltage generation circuit and a read/verification voltage generation circuit. The program voltage generation circuit and the read/verification voltage generation circuit may be implemented by charge pumps. The row decoder 300 decodes an address signal received from the controller 200 to select one or more word lines and sends the program voltage or the read voltage or the verification voltage to the one or more selected word lines.

The memory cell 106 may be implemented by a field-effect transistor having a control gate and a charge trapping layer. The charge trapping layer and a channel region of the field-effect transistor are spaced apart by a tunneling dielectric layer. The control gate and the charge trapping layer are spaced apart by another dielectric layer. The charge trapping layer may be a floating gate or a charge trapping dielectric layer.

As shown in FIG. 2, the memory cells 106 in the column direction are connected in series to constitute a memory cell string 108. Specifically, the memory cells 106 in a same memory cell string 108 are daisy-chained by their sources and drains. Each memory cell string 108 is connected to a corresponding bit line 102 via a first select switch 118. Data can be read via the bit line 102 by a sense amplifier which will be described below. The first select switch 118 controls the connection and disconnection between the memory cell string 108 and the bit line 102. The first select switch 118 is controlled by a first control signal line 114. Each memory cell string 108 is further connected to a common source line 112 via a second select switch 122. The second select switch 122 is controlled by a second control signal line 116. The memory cells 106 in the row direction share a same word line 104, and constitute one page 124. In other words, control gates of the memory cells 106 in a same page are all connected to a same word line 104. In the embodiment shown in FIG. 2, the block 101 includes multiple pages 124, and each page 124 includes multiple pages memory cells.

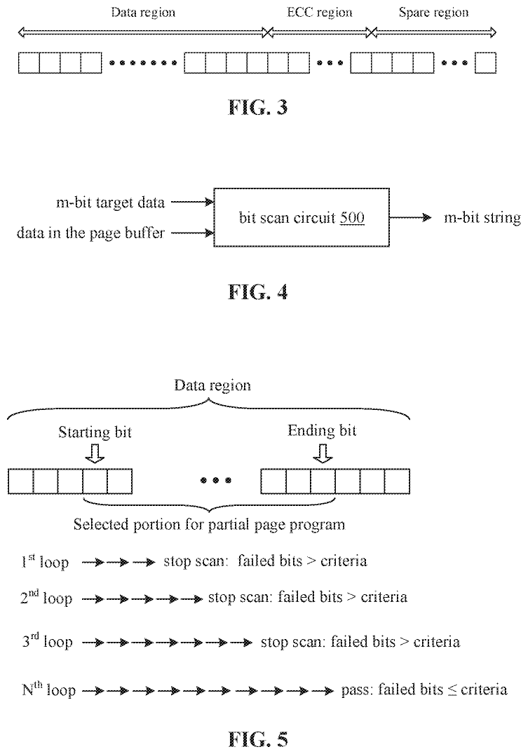

FIG. 3 shows an exemplary configuration of a page 124. Each block in FIG. 3 denotes a corresponding memory cell 106 in the page, and represents one bit. The page 124 includes a data region (main region), an error correction code (ECC) region and a spare region. The data region is used for store data of an end user. Each memory cell in the data region represents a bit of the stored data. ECC is used for correcting bit errors. The data in the data region are stored along with the ECC data. The ECC data provides a way to maintain the information integrity. The spare region is used for storing firmware meta data.

The page buffer 400 may be implemented by a static random access memory (SRAM). The bit scan circuit 500 is used for determining the number of failed bits after a program verification operation or an erase verification operation. The term “failed bits” refers to those memory cells that have not yet reached their desired programmed threshold voltage (or erased threshold voltage, which is typically 0V), as sensed by sense amplifiers in response to the verification voltage applied to the word line by the row decoder 300.

Operations on the flash memory typically include program, erase and read. Briefly, the program operation is an action of adding electrons into the floating gate, whereas the erase operation is an action of moving the electrons from the floating gate to the channel region. Through the program operation, the threshold voltage of the flash memory cell 106 is increased, the flash memory cell 106 is in the programmed state and is regarded as storing information “0”. Through the erase operation, the threshold voltage of the flash memory cell 106 is reduced below 0 V, the flash memory cell 106 is in the erased state, the flash memory cell 106 is regarded as storing information “1”.

In the program operation of the NAND flash memory, a program voltage (e.g., 20V) is applied to the control gate of a selected memory cell 106 via the corresponding word line 104, a pass voltage (e.g., 9V) is applied to the control gates of unselected memory cells 106 in the same string 108, and a voltage of 0V is applied to the bit line 102 connected to the string 108, such that electrons in the channel region move into the floating gate by FN tunneling and are trapped in the floating gate. As a result, the threshold voltage of the memory cell 106 is increased and the memory cell 106 is changed into the programmed state. Typically, the program operation is followed by a verification operation and a bit scan operation, and accordingly the program operation may include multiple loops, each of which includes a program phase, a verification phase, a bit scan phase.

The verification operation and the bit scan operation are described below. After a program voltage is applied to the word line of a selected page, threshold voltages of the memory cells in the page may be changed, but some of them may not reach the desired level. The verification operation is a verification of the states of the memory cells being programmed. In the verification phase, the binary data in the memory cells in this page is read back and retained in the page buffer 400 and may be referred to as the verification result or verification data. In the bit scan phase, the bit scan circuit 500 compares the binary data in the page buffer 400 and the target binary data stored in a register to determine the number of failed bits and determine whether the program operation was performed correctly. Typically, the comparison is performed bit by bit.

In an exemplary embodiment, the bit scan circuit 500 is an XOR circuit, and performs the XOR operation bit-by-bit between the binary data in the page buffer 400 and the target binary data in the register. The result of the XOR operation is an n-bit string where any occurrence of “1” would indicate a memory cell that is not programmed correctly. Of course, in a reverse logic implementation, “0” instead of “1” is used for indicating the memory cell that is not programmed correctly (namely, the failed bit). The bit scan circuit 500 may include n XOR circuits, such that the n bits of the binary data in the page buffer 400 and the target binary data are compared simultaneously. However, the hardware is intensive, and therefore this configuration is uncommon.

In another exemplary embodiment, the bit scan circuit 500 includes a counter. The bit scan circuit 500 compares the binary data in the page buffer 400 and the target binary data in the register bit-by-bit. When one failed bit is detected, the value of the counter is increased by one.

In yet another exemplary embodiment, the bit scan circuit 500 determines which memory cells are correctly programmed and flips their corresponding bits in the page buffer 400 from “0” to “1”, and then the bit scan circuit 500 determines how many bits in the page buffer 400 having the value “0”. The number of bits in the page buffer 400 having the value “0” is equal to the number of failed bits.

With the bit scan circuit 500, the number of memory cells in the data region which are not programmed correctly (the number of failed bits) is obtained. The number of failed bits is used for determining whether this program operation succeeds or not. ECC is used for correcting a limited number of bit errors within the page. The correction capability of ECC is referred to as an ECC tolerable number for representing the maximum quantity of failed bits in the page which can be fixed by the ECC scheme. The correction capability is determined by the number of bits of the ECC region. With the ECC scheme, a certain number of failed bits are allowed in a page. The allowed number of the failed bits in a page is equal to the ECC tolerable number.

The NAND flash memory 10 in this disclosure supports a full page program scheme and a partial page program scheme. For the full page program scheme, the program operation is performed on a page-by-page basis, even if the target data corresponding to merely a portion of one page (that is, the size of the target data is less than the size of the data region of the page). Since the size of the page of the flash memory is larger and larger due to the semiconductor technology development, the size of target data that is received from the host and is to be stored in the memory cell array 100 may be smaller than the size of the page. For the partial page program scheme, the target data corresponds to merely a portion of one page, and the program operation is merely performed on a selected portion of the page rather on the whole page.

For NAND flash memory, an erase operation is required before a program operation. In the page where the program operation is to be performed, the memory cells are firstly changed into the erased state by the erase operation, that is, the page stores 111 . . . 11. Next, selected memory cells in this page are programmed to store 0 according to the target binary data. The number of partial page program operations supported per page before an erase operation (NOP for short) is specified in advance. An example value of NOP is 4. That is, for a page, 4 partial page program operations are allowed between two erase operations, and the 4 partial page program operations are performed on 4 different portions of one page.

For the full page program scheme, the bit scan operation is performed for the whole page. For example, the data region of one page includes n memory cells (that is, n bits), the bit scan circuit 500 compares the data retained in the page buffer 400 (the verification result) and the target data in a bit-by-bit manner starting from the first bit to the last bit.

For the partial page program scheme, the bit scan operation is merely performed on a portion of the page where the partial page program is performed. For example, the target data includes m bits (m<n), the partial page program is performed a selected portion with a size of m bits, and the bit scan operation is also merely performed for the selected portion. In this case, the bit scan circuit 500 compares two m-bit data, and obtains the number of failed bits in the selected portion. The time and power costs are reduced compared with a full page bit scan.

For the partial page program scheme, whether the partial page program succeeds is determined by comparing the number of failed bits with a criteria value. If the number of failed bits is less than or equal to the criteria value, this partial page program succeeds.

In one or more embodiments, the bit scan circuit 500 “scans” the selected portion of the data region of the page after the partial page program performed according to the target data. As shown in FIG. 4, the bit scan circuit 500 compares the m-bit target data with the corresponding bits in the page buffer 400 bit-by-bit, and outputs a m-bit binary string. The controller 200 will count the number of “1”s in the m-bit binary string, and obtain the number of failed bits.

In other embodiments, the bit scan circuit 500 compares the m-bit target data with the corresponding bits in the page buffer 400 bit-by-bit. The comparison may be started from the starting bit of the selected portion in the data region. The value of the starting bit of the selected portion is retained in the corresponding cell of the page buffer 400 by the verification operation. The bit scan circuit 500 compares the starting bit with the first bit of the target data, and outputs a 1-bit result. The controller 200 determines whether the starting bit is a failed bit according to the 1-bit result. Next, the second bit of the selected portion is checked in the above manner, and the controller 200 determines whether the second bit is a failed bit. When the number of the failed bits reaches the criteria value, the bit scan operation is stopped. In this manner, the bit scan circuit 500 does not necessarily scan all the m bits of the selected portion. The bit scan stops when the controller 200 determines that the number of failed bits in the scanned part of the selected portion reaches the criteria value, and does not scan the unscanned part. FIG. 5 shows an example of such bit scan scheme. In the each program loop, the bit scan starts from the starting bit of the selected portion and the controller 200 counts the failed bits along with the bit scan. Assuming that the criteria value is j, upon the controller 200 finds the (j+1)th failed bit, the bit scan stops, and a next program loop is initiated. As shown in FIG. 5, for the first program loop, the second program loop and the third program loop, the (j+1)th failed bit is before the ending bit of the selected portion and the bit scan is not performed for the whole selected portion. In the n^{th} program loop, after the bit scan circuit 500 scans the whole selected portion, the controller 200 finds that the number of failed bits in the selected portion is less than the criteria value and determines that the verification is passed and the partial page program operation succeeds.

The criteria value for determining whether the partial page program operation succeeds is described below.

In an exemplary embodiment, the criteria value is 0. Only when all the memory cells in the selected portion reach their target states, the partial page program is considered to be successful.

In another exemplary embodiment, the criteria value is a number less than the ECC tolerable number. For example, the data region is 2K bytes and the ECC tolerable number is 16, the criteria value for the bit scan is 4.

In another exemplary embodiment, the ECC tolerable number is p, and the criteria value is p/NOP. For another example, the criteria value is equal to k*p, where k is the proportion of selected portion to the whole data region, that is, the criteria value is determined by the size of the target data and the ECC tolerable number.

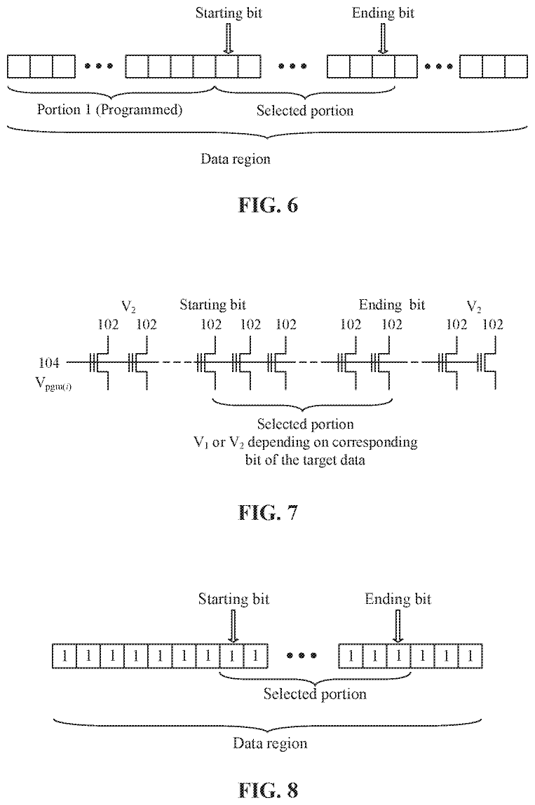

The criteria value may be determined based on the number of times of this partial page program after an erase operation and the number of failed bits of the previous partial page program. In one embodiment, as shown in FIG. 6, the partial page program is the second partial page program after the erase operation, and a first partial page program has been performed in the portion 1. In the first partial page program, data was wrote into the portion 1 and the actual number d₁ of failed bits is less than the criteria value l₁ for the first partial page program. The criteria value l₂ for the second partial page program is determined by the number of failed bits of the first partial page program and the ECC tolerable number p. For example, l₂=(p−d₁)/(NOP−1). Similarly, the criteria value l₃ for the third partial page program is determined based on the number of failed bits of the first partial page program, the number of failed bits of the second partial page program and the ECC tolerable number.

The present disclosure provides a bit scan method for a partial page program. The partial page program is performed on a selected portion of a page according to m-bit target binary data. The bit scan method includes the step of determining whether the number of failed bits in the selected portion is less than or equal to the criteria value, that is determining whether the number of the memory cells which do not reach their target states in the selected portion is less than or equal to the criteria value. This step is implemented by counting the failed bits in the selected portion. In one embodiment, the number of the failed bits in the selected portion is determined, and then is compared with the criteria value. In another embodiment, as shown in FIG. 5 the bit scan stops once the number of failed bits in the scanned part of the selected portion is greater than the criteria value.

The present disclosure provides a partial page program method for the NAND flash memory 10. The partial page program method includes the following steps.

In a first step, the controller 200 selects a portion in the data region of the page according to the target binary data to be stored. For example, the page is 16K bytes and the target binary data is 5K bytes. The controller 200 selects a 5K-bytes portion in the data region, and the memory cells in the selected portion are in the erased state.

In a second step, a partial page program is performed on the selected portion of the data region of the page according to the target binary data. FIG. 7 shows the voltage configuration for the partial page program. A program voltage V_{pgm(i)} is applied to the word line 104 of the page. A program inhibit voltage V₂ (for example, 2.5V) is applied to bit lines 102 corresponding to the memory cells in the unselected portion of the data region. For the memory cell in the selected portion, a voltage V₁ (about 0V) or the program inhibit voltage V₂ is applied to the corresponding bit line 102 based on the bit of the target data corresponding to the memory cell. If the memory cell corresponds to “1”, the program inhibit voltage V₂ is applied to the bit line 102 connected to the memory cell. If the memory cell corresponds to “0”, the voltage V₁ is applied to the bit line 102 connected to the memory cell.

In a third step, the program verification is performed with a sense amplifier circuit. The states of the memory cells in the selected page are verified, and the verification result is retained in the page buffer 400.

In a fourth step, a bit scan operation is performed on merely the selected portion to determine whether the number of failed bits in the selected portion is greater than the criteria value. The bit scan operation is described above and is not repeated here.

If the number of failed bits is less than or equal to the criteria value, the partial page program succeeds. If the number of failed bits is greater than the criteria value, the partial page program needs to be performed again.

An example of the above partial page program method of the NAND flash memory 10 is described below with specific embodiments.

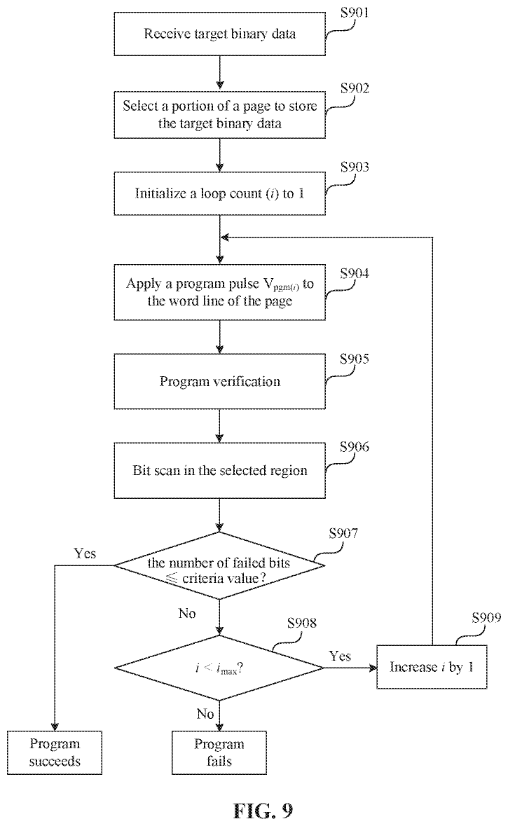

FIG. 9 is a flowchart of a partial page program method provided by this disclosure. This partial page program method is based on the ISPP method. As shown in FIG. 9, in step 901, the controller 200 receives target binary data. The size of the target binary data is smaller than the size of the data region of the page.

In step 902, the controller 200 selects a portion in the data region of the page, and determines the starting bit and the ending bit for the selected portion. The size of the selected portion is equal to the size of the target binary data. FIG. 8 shows the selected portion in the data region of the page. The selected portion includes successive memory cells. In the embodiment shown in FIG. 8, the present partial page program is the first program performed on this page after an erase operation. Before the present partial page program, each memory cell in the data region stores “1”.

In step 903, the incremental step pulse programming (ISPP) method is started. The loop count i is used for representing the sequence number of the program loop in this partial page program.

In step 904, a program pulse V_{pgm(i)} is applied to the word line of the page, the pass voltage is applied to other word lines in the block, the bit lines corresponding to the unselected portion are biased at the program inhibit voltage V₂, and the bit lines corresponding to the selected portion are each biased at either the voltage V₁ of 0V or the program inhibit voltage V₂.

In step 905, the program verification is performed, and the verification result is stored in the page buffer 400.

In step 906, the bit scan operation is performed for the selected portion.

In the bit scan, the bit scan circuit 500 compares bits in the verification result corresponding to the target data and the target data in a bit-by-bit manner and outputs a binary string, and the number of the failed bits is determined by counting the number of “1”s in the binary string.

In step 907, it is determined whether the number of failed bits is less than or equal to the criteria value. if the number of failed bits is less than or equal to the criteria value, the partial page program succeeds and the method ends. If the number of failed bits is greater than the criteria value, the method proceeds to step 908.

In step 908, it is determined whether the current loop count i is less than a maximum value iₘₐₓ. If the loop count i is less than iₘₐₓ, the method proceeds to step 909. In step 909, the loop count i is increased by 1, the program pulse V_{pgm(i)} is increased by a step size ΔV_{pgm}, and a next program pulse is applied to the word line of the page.

If the loop count i is equal to or greater than imax, this partial page program fails and the method ends.

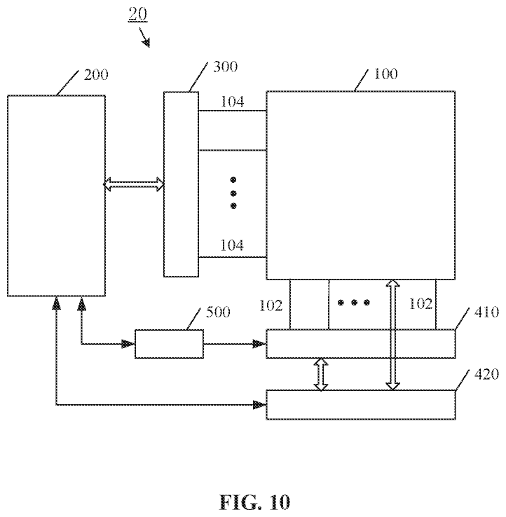

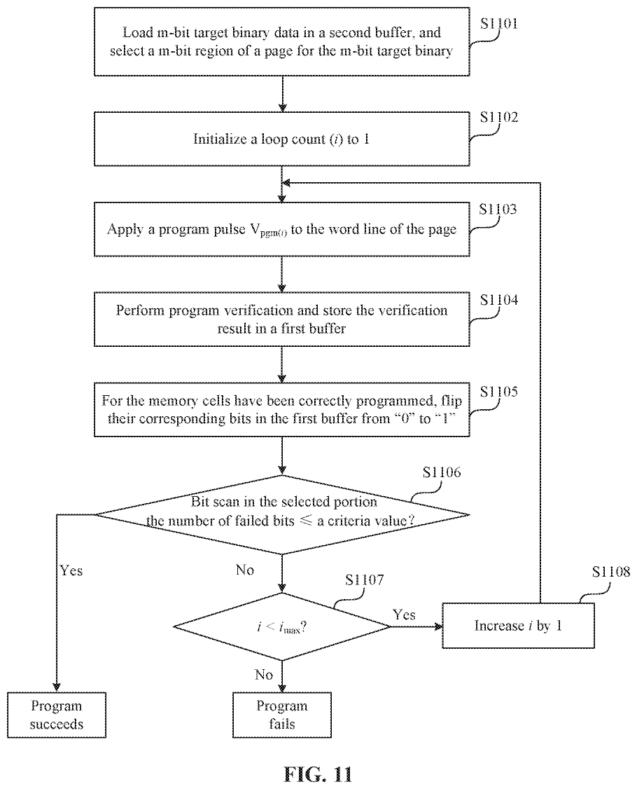

FIG. 10 is a simplified block diagram of another flash memory according to an embodiment of the present disclosure, same reference numerals in FIG. 10 and FIG. 1 represent the same elements. The flash memory 20 includes a memory cell array 100, a controller 200, a row decoder 300, a first buffer 410, a second buffer 420, and a bit scan circuit 500. The first buffer 410 and the second buffer 420 may be implemented by SRAMs. The memory cell array 100 includes multiple blocks, each block includes multiple pages, and each page includes a n-bit data region and an ECC region. Exemplarily, the size of the first buffer 410, the size of the second buffer 420, and the size of the page are equal.

FIG. 11 is a flowchart of a partial page program method for the flash memory in FIG. 10. As shown in FIG. 11, the partial page program method includes the following steps.

In step 1101, m-bit target binary data is loaded into the second buffer 420 from the controller 200, and a m-bit portion in the data region is selected for the m-bit target binary data. For example, the m-bit portion is from the (i+1)th memory cell to the (i+m)th memory cell in the data region.

In step 1102, the incremental step pulse programming method is started.

In step 1103, a program pulse V_{pgm(i)} is applied to the word line of the page by the row decoder 300 with the program voltage generation circuit, the pass voltage is applied to other word lines in the block, the bit lines corresponding to the unselected portion are biased at the program inhibit voltage V₂ , and the bit lines corresponding to the selected portion are each biased at either the voltage V₁ of 0V or the program inhibit voltage V₂ according to the m-bit target binary data.

In step 1104, the program verification is performed. In the program verification, the verification result is read out by the sensing amplifier and is stored in the first buffer 410. The memory cells which have been correctly programmed are determined according to the verification result and the target data. For a memory cell to be programmed, its corresponding bit in the target binary data in the second buffer 420 is “0”. If the memory cell is correctly programmed, its corresponding bit in the first buffer 410 is “0”. If the memory cell is not correctly programmed, its corresponding bit in the first buffer 410 is “1”.

In step 1105, for the memory cells which have been correctly programmed, their corresponding bits in the first buffer 410 are flipped from “0” to “1”, for example, by the controller 200.

In step 1106, the bit scan operation is performed for the selected portion, the number of “0”s in the first buffer 410 is obtained and then compared with the criteria value. The number of “0”s in the first buffer 410 is equal to the number of failed bits in the selected portion. If the number of failed bits is less than or equal to the criteria value, this partial page program succeeds. If the number of failed bits is greater than the criteria value, the method proceeds to step 1107.

In another embodiment of step 1106, the bit scan circuit 500 has a counter, and in the bit scan operation, the bit scan circuit 500 “scans” the first buffer 410 from the (i+1)th memory cell. The value of the counter is increased by 1 once a bit of “0” is detected. In response to determine that the value of the counter is greater than the criteria value, the bit scan stops and the method proceeds to step 1107.

In an exemplary in which the criteria value is 0, the bit scan circuit 500 “scans” the first buffer 410 from the (i+1)th memory cell. Once a bit of “0” is detected in the first buffer 410, the bit scan stops and the method proceeds to step 1107. If all bits in the first buffer 410 are “1”, it indicates that the number of failed bits is 0, and this partial page program succeeds.

In step 1107, it is determined whether the current loop count i is less than a maximum value iₘₐₓ. If the loop count i is less than iₘₐₓ, the method proceeds to step 1108. In step 1108, the loop count i is increased by 1, the program pulse V_{pgm(i)} is increased by a step size ΔV_{pgm}, and a next program pulse is applied to the word line of the page.

If the loop count i is equal to or greater than iₘₐₓ, this partial page program fails and the method ends.

In various embodiments, the nonvolatile memory is at least one of a multimedia card (MMC) card, a Secure Digital (SD) card, a micro SD card, a memory stick, an ID card, a PCMCIA card, a chip card, a USB card, a smart card, and a Compact Flash (CF) card.

The nonvolatile memory may be packaged by a Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (S SOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and the like.

While exemplary embodiments are described above, it is not intended that these embodiments describe all possible forms encompassed by the claims. The words used in the specification are words of description rather than limitation, and it is understood that various changes may be made without departing from the spirit and scope of the disclosure and claims. As previously described, the features of various embodiments may be combined to form further embodiments of the disclosure that may not be explicitly described or illustrated. While various embodiments may have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to: cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A bit scan method for a partial page program, the partial page program being performed on a selected portion of a page of a NAND flash memory according to target binary data, the bit scan method comprising:
counting failed bits only in the selected portion of the page.

2. The bit scan method according to claim 1, wherein the step of counting failed bits only in the selected portion of the page comprises: comparing verification data of the partial page program with the target binary data bit-by-bit.

3. The bit scan method according to claim 2, wherein the step of comparing verification data of the partial page program with the target binary data stops in response to determining that a quantity of counted failed bits exceeds a criteria value.

4. The bit scan method according to claim 3, wherein the criteria value is 0.

5. The bit scan method according to claim 3, wherein the page comprises a data region and an error correction code (ECC) region, the selected portion is within the data region, and the criteria value is greater than or equal to 0 and less than or equal to an ECC tolerable number.

6. A partial page program method, comprising:
at a NAND flash memory having a page, the page comprising a n-bit data region and an ECC region:
performing a partial page program on a m-bit portion of the data region according to m-bit target binary data, wherein m is less than n; and
counting failed bits in the m-bit portion.

7. The partial page program method according to claim 6, wherein the step of counting failed bits in the m-bit portion comprises: comparing verification data of the partial page program with the target binary data bit-by-bit.

8. The partial page program method according to claim 7, wherein the step of comparing verification data of the partial page program with the target binary data stops in response to determining that a quantity of counted failed bits exceeds a criteria value.

9. The partial page program method according to claim 8, wherein the criteria value is 0.

10. The partial page program method according to claim 8, wherein the criteria value is greater than or equal to 0 and less than or equal to an ECC tolerable number.

11. The partial page program method according to claim 6, further comprising:
comparing a quantity of the failed bits in the m-bit portion with a criteria value; and
determining that the partial page program successes when the quantity of the failed bits in the m-bit portion is less than or equal to the criteria value, and determining that the partial page program fails when the quantity of the failed bits in the m-bit portion is greater than the criteria value.

12. The partial page program method according to claim 6, wherein each bit of the target binary data has either a first value or a second value, and the m-bit portion of the data region comprises m memory cells, each of which corresponds to a respective one bit of the target binary data, wherein the step of performing a partial page program on the m-bit portion of the data region according to the m-bit target binary data comprises:
applying a program voltage to a word line of the page;
applying a first voltage to bit lines which are electrically connected to the memory cells corresponding to the bits having the first value; and
applying a second voltage to other bit lines corresponding to the page, the first voltage being less than the second voltage,
wherein the step of counting failed bits in the m-bit selected portion comprises:
performing a program verification for the partial page program to obtain verification data;
performing an XOR operation between the target binary data and m bits of the verification data corresponding to the target binary data to obtain a m bit binary string; and
counting the number of bits having the value of “1” in the m bit binary string.

13. A NAND flash memory, comprising:
a page having a n-bit data region and an ECC region;
a first buffer;
a second buffer; and
a controller,
wherein the controller is configured to:
load m-bit target binary data into the second buffer;
perform a partial page program on a m-bit portion of the data region according to the m-bit target binary data, wherein m is less than n;
perform a program verification for the partial page program and retain verification data in the first buffer; and
count failed bits in the m-bit portion.

14. The NAND flash memory according to claim 13, wherein the controller is configured to compare the verification data of the partial page program with the target data bit-by-bit.

15. The NAND flash memory according to claim 14, wherein the controller stops comparing the verification data with the target data in response to determining that a quantity of counted failed bits exceeds a criteria value.

16. The NAND flash memory according to claim 15, wherein the criteria value is 0.

17. The NAND flash memory according to claim 15, wherein the criteria value is greater than or equal to 0 and less than or equal to an ECC tolerable number.

18. The NAND flash memory according to claim 15, wherein each bit of the target binary data has either a first value or a second value, and the m-bit portion of the data region comprises m memory cells, each of which corresponds to a respective one bit of the target binary data,
wherein the controller is further configured to flip a bit in the target binary data in the second buffer, to which a memory cell corresponding passes the program verification, from the first value to the second value, and then count the number of bits having the first value in the second buffer.

19. The NAND flash memory according to claim 13, wherein the controller is further configured to:
compare a quantity of the failed bits in the m-bit portion with a criteria value; and
determine that the partial page program successes when the quantity of the failed bits in the m-bit portion is less than or equal to the criteria value, and determine that the partial page program fails when the quantity of the failed bits in the m-bit portion is greater than the criteria value.

20. The NAND flash memory according to claim 13 is a single-level cell NAND flash memory.
